(19) United States
(12) Patent Application Publication
(10) Pub. No.: US 2016/0064265 A1
(43) Pub. Date: Mar. 3, 2016

(54) TEMPORARILY BONDING SUPPORT SUBSTRATE AND SEMICONDUCTOR DEVICE MANUFACTURING METHOD

(71) Applicant: KABUSHIKI KAISHA TOSHIBA, Tokyo (JP)

(72) Inventor: Kenro NAKAMURA, Oita Oita (JP)

(73) Assignee: KABUSHIKI KAISHA TOSHIBA, Tokyo (JP)

(21) Appl. No.: 14/634,389

(22) Filed: Feb. 27, 2015

(30) Foreign Application Priority Data
Aug. 27, 2014 (JP) 2014-173146

(51) Int. Cl. H01L 21/683

(52) U.S. Cl. CPC H01L 21/6836

(57) ABSTRACT

According to one embodiment, there is provided a temporarily bonding support substrate including an underlayer and a heat generable layer. A device substrate is to be temporarily bonded to the heat generable layer on an opposite side of the underlayer.

### CROSS-REFERENCE TO RELATED APPLICATIONS

This application is based upon and claims the benefit of priority from Japanese Patent Application No. 2014-173146, filed on Aug. 27, 2014; the entire contents of which are incorporated herein by reference.

### FIELD

Embodiments described herein relate generally to a temporarily bonding support substrate and a semiconductor device manufacturing method.

### BACKGROUND

It is sometimes required to temporarily bond a support substrate to a device substrate so as to process the device substrate and, after the process finishes, to remove the support substrate from the device substrate. At this time, it is desired to be able to smoothly remove the support substrate from the device substrate.

### BRIEF DESCRIPTION OF THE DRAWINGS

FIG. 1 is a cross-sectional view showing the configuration of a temporarily bonding support substrate according to a first embodiment;

FIG. 2 is a diagram showing a semiconductor device manufacturing method using the temporarily bonding support substrate according to the first embodiment;

FIG. 3 is a diagram showing the semiconductor device manufacturing method using the temporarily bonding support substrate according to the first embodiment;

FIG. 4 is a diagram showing the semiconductor device manufacturing method using the temporarily bonding support substrate according to the first embodiment;

FIG. 5 is a diagram showing the semiconductor device manufacturing method using the temporarily bonding support substrate according to the first embodiment;

FIG. 6 is a diagram showing the semiconductor device manufacturing method using the temporarily bonding support substrate according to the first embodiment;

FIG. 7 is a diagram showing the semiconductor device manufacturing method using the temporarily bonding support substrate according to the first embodiment;

FIG. 8 is a diagram showing the semiconductor device manufacturing method using the temporarily bonding support substrate according to the first embodiment;

FIG. 9 is a diagram showing the configuration of a temporarily bonding support substrate according to a modified example of the first embodiment;

FIG. 10 is a diagram showing the configuration of a temporarily bonding support substrate according to another modified example of the first embodiment;

FIG. 11 is a diagram showing the configuration of a temporarily bonding support substrate according to yet another modified example of the first embodiment;

FIG. 12 is a diagram showing the configuration of a temporarily bonding support substrate and a semiconductor device manufacturing method using the temporarily bonding support substrate according to a second embodiment;

FIG. 13 is a diagram showing the configuration of a temporarily bonding support substrate and a semiconductor device manufacturing method using the temporarily bonding support substrate according to a third embodiment; and

FIG. 14 is a diagram showing the configuration of a temporarily bonding support substrate and a semiconductor device manufacturing method using the temporarily bonding support substrate according to a fourth embodiment.

### DETAILED DESCRIPTION

In general, according to one embodiment, there is provided a temporarily bonding support substrate including an underlayer and a heat generable layer. The heat generable layer is provided on the underlayer. A device substrate is to be temporarily bonded to the heat generable layer on an opposite side of the underlayer.

Exemplary embodiments of a temporarily bonding support substrate will be explained below in detail with reference to the accompanying drawings. The present invention is not limited to the following embodiments.

It should be noted that, in this specification, “a first layer is provided on a second layer” includes not only a case where a first layer is contacted on a second layer but also a case where a third layer is sandwiched between the first layer and the second layer.

### First Embodiment

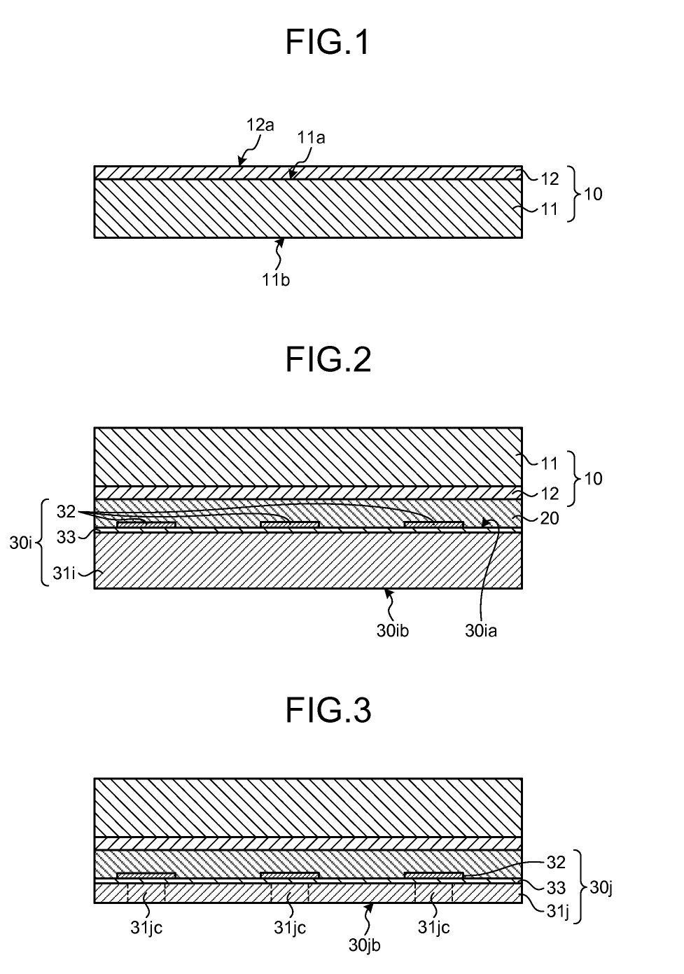

A temporarily bonding support substrate 10 according to the first embodiment will be described using FIG. 1. FIG. 1 is a cross-sectional view showing the configuration of the temporarily bonding support substrate 10.

As a new approach to making semiconductor-device mounting density higher, three-dimensional mounting technology is in the spotlight in which semiconductor chips are stacked three-dimensionally to produce a stacked-type semiconductor device. In order to obtain a stacked-type semiconductor device, a plurality of semiconductor chips need to be stacked in the semiconductor-device packaging process. At this time, through silicon vias (TSVs) extending through a device substrate (semiconductor substrate) are formed, and the device substrate is cut and divided with a dicing blade into individual semiconductor chips. Then a stacked-type semiconductor device is formed by stacking a plurality of semiconductor chips.

At this time, in order to easily form the through silicon vias, the device substrate needs to be made thinner. Making a device substrate thinner, in which elements are to be formed, is performed by grinding and polishing the device substrate at the back side, so that the thickness is finally, e.g., about 50 μm. Hence, the temporarily bonding support substrate 10 for stably holding the device substrate in grinding and polishing needs to be temporarily bonded to the front surface 30ia of the device substrate 30i (see FIG. 2).

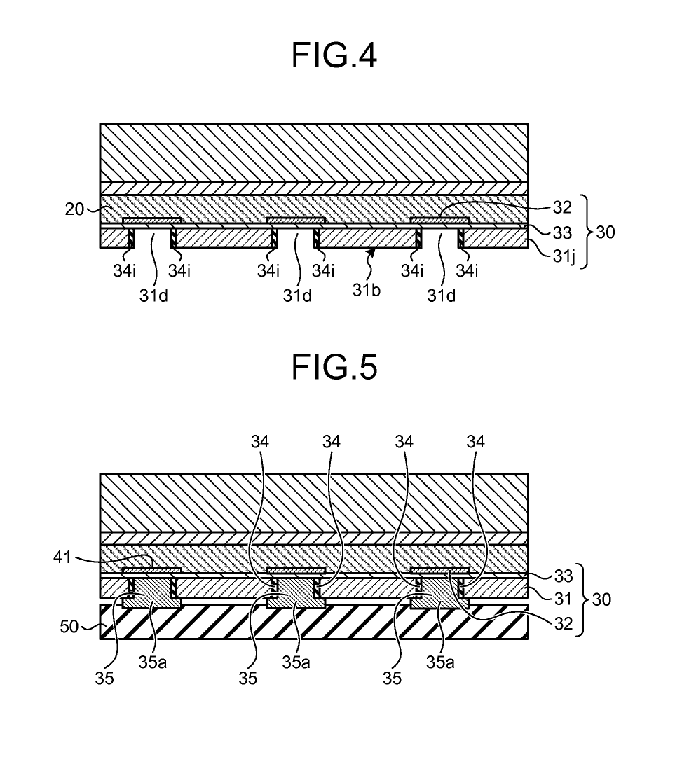

The temporarily bonding support substrate 10 is removed from the device substrate (see FIG. 7) by the time that the device substrate is divided into individual semiconductor chips. The types of processes that are executed during the time from temporary bonding to removal differ depending on the method of forming junction electrodes between chips and the joining method. They may be only back-side grinding and polishing or include a process of forming openings in the device substrate (e.g., a silicon substrate) (see FIG. 4) and a high-temperature film forming process. That is, it is necessary to ensure stable adhering with enduring the environment where mechanical separation and thermal separation are likely to happen while temporarily bonded. In contrast, it is desired to be able to smoothly remove the device substrate from the support substrate when removing.

It is a highly difficult task to solve antinomic propositions in temporarily bonding that are stable adhering while temporarily bonded and easy removal when removing.

Facing these propositions, one could think of adopting tactics in the material and structure of the adhering layer to deal with them. To put it simply, one could think of a method which provides a portion corresponding to a “removal layer” in the adhering layer and dissolves this portion with a solvent or decomposes it by laser light irradiation or the like so as to separate the device substrate and the support substrate.

However, in a case where the portion is dissolved with a solvent, because the adhering layer is of a three-layered structure where a release layer is provided between an adhering layer on the device substrate side and an adhering layer on the support substrate side, there is the possibility that it may be difficult to keep the thickness of the entire adhering layer uniform. As variation in this thickness becomes greater, variation in the thickness of the device substrate after made thinner also becomes greater. Further, since the adhering layer is of a three-layered structure, the production cost of the semiconductor device may increase. Yet further, because directions in which the solvent enters the release layer are limited to sideways of the release layer, the processing time is likely to become longer.

In a case where the portion is decomposed by laser light irradiation or the like, the material of the support substrate is limited to a material whose transparency to light is high such as glass, and it is difficult to use a material whose transparency to light is low such as silicon, which is thought to be convenient in practical use. Further, because the material of the adhering layer is limited to a special material having the property of decomposing by light irradiation, the production cost of the semiconductor device is likely to increase.

In the present embodiment, stable adhering while temporarily bonded and removal easiness when removing are realized not by tactics in the material and structure of the adhering layer but by tactics in the material and structure of the support substrate.

Specifically, the temporarily bonding support substrate 10 has an underlayer 11 and a heat generation layer 12 as shown in FIG. 1. In the temporarily bonding support substrate 10, the surface 12a of the heat generable layer 12 is to be temporarily bonded to the device substrate 30i (see FIG. 2).

The underlayer 11 is required to have support rigidity to support the device substrate 30i so as to be in a substantially flat shape while the device substrate 30i is being ground and polished with the temporarily bonding support substrate 10 being temporarily bonded thereto. The underlayer 11 has a thickness and a property in material according to the required support rigidity. The underlayer 11 has a thickness of, e.g., 750 μm or greater. The underlayer 11 is formed of, e.g., a material made mainly of silicon or silicon oxide. In a case where the underlayer 11 is formed of a material made mainly of silicon, the production cost of the temporarily bonding support substrate 10 can be easily reduced as compared with a case where the underlayer 11 is formed of a material made mainly of silicon oxide (glass).

The heat generable layer 12 is placed on the side of the underlayer 11 which is to be temporarily bonded to the device substrate 30i (see FIG. 2) via adhesive 20. For example, the heat generable layer 12 is provided on the underlayer 11 and covers the principal surface 11a on the side of the underlayer 11, the side being to be temporarily bonded to the device substrate 30i. The heat generable layer 12 can be formed by depositing material for it on the principal surface 11a of the underlayer 11 by, e.g., a CVD method or sputtering method. The heat generable layer 12 has a thickness of, e.g., about 10 μm.

The heat generable layer 12 is formed of a material that can generate heat to cause heat deterioration the adhesive 20 with being temporarily bonded to the device substrate 30i via the adhesive 20. The heat generable layer 12 is greater in absorptivity to electromagnetic waves of wavelengths longer than those of visible light than the underlayer 11. The electromagnetic waves of wavelengths longer than those of visible light are electromagnetic waves of frequencies of 400 THz or less and are, for example, infrared radiation. That is, the heat generable layer 12 is greater in absorptivity to infrared radiation than the underlayer 11. The heat generable layer 12 can be formed of a material made mainly of carbon or tungsten. Or the heat generable layer 12 can be formed of silicon highly increased in conductivity by doping an impurity. Thus, when infrared radiation is irradiated toward the heat generable layer 12 from the principal surface 11b side opposite to the principal surface 11a of the underlayer 11, the heat generable layer 12 can be made to generate, at the surface 12a, heat necessary to cause heat deterioration of the adhesive 20 covering the surface 12a of the heat generable layer 12 (see FIG. 2).

Next, a semiconductor device manufacturing method using the temporarily bonding support substrate 10 will be described using FIGS. 2 to 8.

In the present embodiment, the heat generable layer 12 to be heated by electromagnetic waves of frequencies of 400 THz or less is provided on the adhering surface side of the temporarily bonding support substrate 10. The embodiment presents a technique in which, after temporarily bonding, by irradiating electromagnetic waves to heat the heat generable layer 12, a portion adjacent to the interface of the adhesive 20 touching the heat generable layer 12 is subject to heat deterioration so that the temporarily bonding support substrate 10 is removed from the device substrate 30. At this time, because of adopting tactics in the structure and material of the temporarily bonding support substrate 10 to perform removal specific to the temporarily bonding support substrate 10, the adhesive 20 can have general versatility.

Specifically, in the process shown in FIG. 2, the temporarily bonding support substrate 10 having the underlayer 11 and the heat generable layer 12 is formed by depositing material for the heat generable layer 12 on the principal surface 11a (see FIG. 1) of the underlayer 11 by, e.g., a CVD method or sputtering method. Meanwhile, the device substrate 30i is formed by forming a device layer 33 on a surface of the semiconductor substrate 31i and forming front-side electrodes 32 on the surface of the device layer 33. The device layer 33 may include a multilayer wiring structure and elements such as transistors, and the front-side electrodes 32 may be electrically connected to the multilayer wiring structure and elements in the device layer 33. The surface of the device layer 33 and the surfaces of the front-side electrodes 32 form the front surface 30ia of the device substrate 30i.

Next, the adhesive 20 is coated to cover the front surface 30ia of the device substrate 30i, and the temporarily bonding support substrate 10 is temporarily bonded to the device substrate 30i via the adhesive 20. The adhesive 20 is, for example, of a thermosetting type. The thermosetting temperature of the adhesive 20 is, for example, about 180° C.

In the process shown in FIG. 3, the back surface 30ib of the device substrate 30i is polished and ground by mechanical grinding or the like. Thus, the device substrate 30j (the semiconductor substrate 31j) becomes thinner. The device substrate 30j is made as thin as, for example, about 50 μm. Where the device substrate 30i is made thinner, after mechanical grinding is performed, the back surface 30jb of the device substrate 30j can be made a mirror surface by a CMP method or the like.

In the process shown in FIG. 4, regions 31jc (see FIG. 3) corresponding to the front-side electrodes 32 in the device substrate 30j (the semiconductor substrate 31j) are removed using a photolithography technique and a dry etching technique. Thus, a device substrate 30 having formed therein through holes 31d through which the back surface of the device layer 33 is partially exposed, can be obtained.

Then, an insulating film 34i is formed on the inner side surfaces of the through holes 31d by a thermal CVD method or the like. At this time, the adhesive 20 for temporarily bonding the temporarily bonding support substrate 10 to the device substrate 30 is exposed to the thermal process (e.g., a substrate temperature close to 200° C.) while the support substrate 10 is temporarily bonded, and hence a certain degree of heat resistance is required of the adhesive 20. However, if the adhesive is too high in heat resistance as is an inorganic adhesive such as water glass, then it is difficult to remove after temporarily bonding. From the viewpoint of moderate heat resistance, thermosetting adhesive 20 can be used.

In the process shown in FIG. 5, by filling the through holes 31d with conductive material and patterning the back side, through electrodes 35 having back-side electrodes 35a on the back side are formed. The through electrodes 35 are insulated from the semiconductor substrate 31 by the insulating film 34 covering the inner side surfaces of the through holes 31d. The through electrodes 35 may be electrically connected to the multilayer wiring structure and elements in the device layer 33. Then, a pickup tape 50 is stuck to the back-side electrodes 35a of the through electrodes 35.

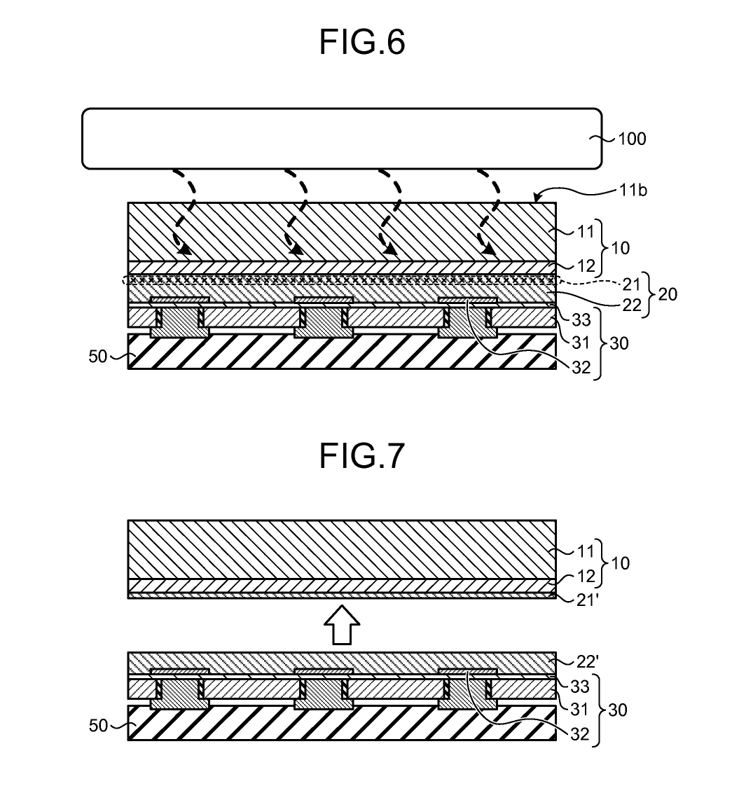

In the process shown in FIG. 6, the heat generable layer 12 is made to generate heat so as to cause heat deterioration of the adhesive 20. That is, infrared radiation is irradiated onto the temporarily bonding support substrate 10 temporarily bonded to the device substrate 30 from the underlayer 11 side.

Specifically, an infrared radiation source 100 is placed in a position facing the principal surface 11b of the underlayer 11 of the temporarily bonding support substrate 10. As the infrared radiation source 100, a lamp having high spectral emissivity in the infrared range (e.g., an infrared lamp) may be used, or a halogen lamp may be used. The infrared radiation source 100 is made to operate so that infrared radiation emitted from the infrared radiation source 100 is irradiated onto the temporarily bonding support substrate 10 from the underlayer 11 side as indicated by broken-line arrows in FIG. 6. The radiation intensity of the infrared radiation source 100 can be set at, e.g., about 5 W/cm². The irradiation time of infrared radiation by the infrared radiation source 100 can be set at, e.g., about several seconds.

At this time, of the temporarily bonding support substrate 10, absorptivity to infrared radiation in the heat generable layer 12 is greater than absorptivity to infrared radiation in the underlayer 11. Thus, infrared radiation irradiated onto the temporarily bonding support substrate 10 is efficiently absorbed by the heat generable layer 12 to make the heat generable layer 12 generate heat. The heat generated in the heat generable layer 12 causes heat deterioration of a portion 21 of the adhesive 20 adjacent to the heat generable layer 12.

The portion 21 to be subject to heat deterioration is a small portion of the adhesive existing adjacent to the interface between the heat generable layer 12 of the temporarily bonding support substrate 10 and the adhesive 20. Therefore, a small amount of energy is enough to cause heat deterioration. By supplying this thermal energy locally efficiently to the adhesive 20, the portion 21 that is a part of the adhesive 20 is subject to heat deterioration. If the adhesive 20 is of a thermosetting type, the portion 21 is heated to a temperature higher than the thermosetting temperature (180° C.). The portion 21 is heated to, e.g., about 200 to 350° C. by the heat generable layer 12.

From the viewpoint of this locality and efficiency, not hot-plate heating based on heat conduction but infrared-radiation heating based on heat radiation is adopted. This electromagnetic-wave heating (infrared-radiation heating) of the heat generable layer 12 allows to suppress heating a portion 22 located on the side of device substrate 30 while locally heating the portion 21 of the adhesive 20 adjacent to the interface with the heat generable layer 12. Thus, a steep temperature profile can be realized in which the portion 21 of the adhesive 20 adjacent to the interface with the temporarily bonding support substrate 10 becomes high in temperature while the pickup tape 50 stuck to the back of the device substrate 30 remains low in temperature.

From the viewpoint of maintaining the steep temperature profile for a long time, the heat generable layer 12 needs to be of an appropriate thickness (for example, about 10 μm thick). This is because, if the heat generable layer 12 is too thick, an excess of heat from the heat generable layer 12 is conducted from the adhesive 20 to the device substrate 30 to the pickup tape 50, so that the pickup tape 50 may increase in temperature to suffer thermal damage.

In the process shown in FIG. 7, the temporarily bonding support substrate 10 is removed from the device substrate 30. The specific method of removing is decided on depending on to what extent the adhesiveness to the temporarily bonding support substrate 10 of the adhesive 20 is restored when portion 21 having been subject to heat deterioration has re-solidified.

At this time, if the adhesive 20 is of a thermosetting type, heat deterioration when heated is the thermal decomposition of cross-linked structures in the portion 21, and thus the adhesiveness is hardly likely to recover even when the temperature drops. That is, the removal need not be performed while the heat generable layer 12 is heated to cause heat deterioration of the portion 21. Because the removal can be performed when the temperature has dropped, an usual room-temperature removal method can be used after the infrared radiation source 100 is evacuated.

Alternatively, if the adhesive 20 is of a hot-melting type, heat deterioration when heated is the melting and softening of the portion 21, and thus the adhesiveness may recover when the temperature drops. If the adhesiveness recovers when the temperature drops, then the removal needs to be performed while the heat generable layer 12 is being heated to cause heat deterioration of the portion 21. Therefore, there are hurdles associated with the use that the removal needs to be performed in such a way as not to interfere with the infrared radiation source 100, and so on. For example, a method is adopted which slides the temporarily bonding support substrate 10 sideways to remove with the placement of the infrared radiation source 100 remaining the same. Or a method which moves not the temporarily bonding support substrate 10 but the device substrate 30 having the pickup tape 50 stuck thereto to remove can also be adopted. This fact is true of thermoplastic adhesive 20. Both the hot-melting type and the thermoplastic type of adhesive 20 can be used in this embodiment, but the thermosetting adhesive 20 is convenient to use.

That is, because the portion 21 having been subject to heat deterioration is weakened in chemical cohesion, it can be easily separated from the other portion 22. Thus, the temporarily bonding support substrate 10 to which the portion 21′ is adhering can be removed from the device substrate 30 to which the portion 22′ is adhering.

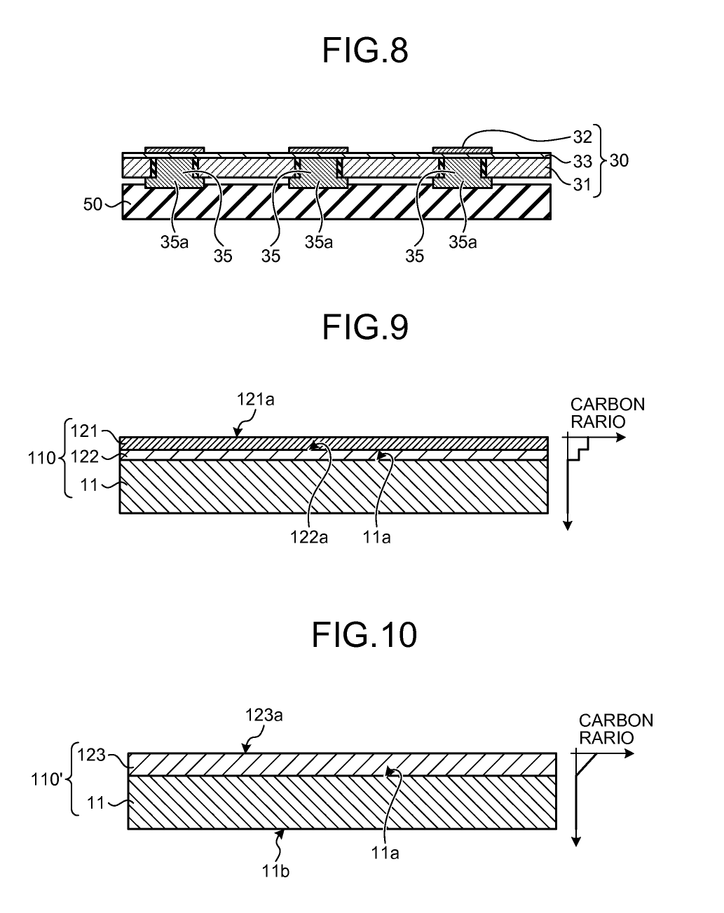

In the process shown in FIG. 8, the portion 22′ adhering to the device substrate 30 is removed from the device substrate 30. That is, after the removal in the process shown in FIG. 7, the portion 22′ of the adhesive remains adhering to the device substrate 30, but the entire surface of the portion 22′ is exposed. Thus, the portion 22′ can be easily removed by usual processing such as wet etching or dry etching. For example, it is removed by wet etching with an organic solvent.

It should be noted that, although part of the portion 21′ of the adhesive 20 may remain adhering to the temporarily bonding support substrate 10, it can be washed off with an organic solvent to reuse the temporarily bonding support substrate 10.

The obtained device substrate 30 is cut and divided with a dicing blade, and removed from the pickup tape 50, into a plurality of semiconductor chips. Then the plurality of divided-into semiconductor chips are stacked, and the back-side electrodes 35a of a semiconductor chip located above and the front-side electrodes 32 of a semiconductor chip located below are joined. By this means, the plurality of semiconductor chips are electrically connected via the through electrodes 35 to form a stacked-type semiconductor device.

As described above, in the first embodiment, in the temporarily bonding support substrate 10, the heat generable layer 12 is placed on the side of the underlayer 11 which is temporarily bonded to the device substrate 30 via the adhesive 20. The heat generable layer 12 in the state of being temporarily bonded to the device substrate 30 via the adhesive 20 can generate heat to cause heat deterioration of the adhesive 20. By this means, chemical cohesion in the portion having been subject to heat deterioration in the adhesive 20 can be weakened, and with the portion weakened in chemical cohesion, the temporarily bonding support substrate 10 can be separated from the device substrate 30. As a result, in a case where the temporarily bonding support substrate 10 is temporarily bonded to the device substrate 30 via the adhesive 20 strengthened in adhesiveness, the temporarily bonding support substrate 10 can be smoothly removed from the device substrate 30 after the process finishes. That is, strong adhering while temporarily bonded and easy removal after temporarily bonding can both be realized.

Further, in the first embodiment, strong adhering while temporarily bonded and easy removal after temporarily bonding can be realized by adopting tactics in the temporarily bonding support substrate 10, and hence it is easy to make the adhesive 20 have general versatility.

Yet further, in the first embodiment, in the temporarily bonding support substrate 10, the heat generable layer 12 is greater in absorptivity to electromagnetic waves of wavelengths longer than those of visible light (e.g., infrared radiation) than the underlayer 11. Thus, when electromagnetic waves of wavelengths longer than those of visible light are irradiated toward the heat generable layer 12 from the principal surface 11b side of the underlayer 11, the heat generable layer 12 can be made to efficiently absorb the irradiated electromagnetic waves (e.g., infrared radiation) so as to generate heat.

In the first embodiment, in the temporarily bonding support substrate 10, the underlayer 11 is formed of a material made mainly of silicon or silicon oxide, and the heat generable layer 12 is formed of a material made mainly of carbon or tungsten. Thus, absorptivity to infrared radiation in the heat generable layer 12 can be made greater than absorptivity to infrared radiation in the underlayer 11. Further, if the underlayer 11 is formed of a material made mainly of silicon, the production cost of the temporarily bonding support substrate 10 can be easily reduced.

In the first embodiment, in the semiconductor device manufacturing method, the surface 12a of the heat generable layer 12 in the temporarily bonding support substrate 10 is temporarily bonded to the device substrate 30 via the adhesive 20. Then, by making the heat generable layer 12 generate heat to cause heat deterioration of the adhesive 20, the temporarily bonding support substrate 10 is removed from the device substrate 30. By this means, chemical cohesion in the portion having been subject to heat deterioration in the adhesive 20 can be weakened, and with the portion weakened in chemical cohesion, the temporarily bonding support substrate 10 can be easily removed from the device substrate 30. As a result, in a case where the temporarily bonding support substrate 10 is temporarily bonded to the device substrate 30 via the adhesive 20 strengthened in adhesiveness, the temporarily bonding support substrate 10 can be smoothly removed from the device substrate 30 after the process finishes. That is, strong adhering while temporarily bonded and easy removal after temporarily bonding can both be realized.

Further, in the first embodiment, in the semiconductor device manufacturing method, by irradiating electromagnetic waves of wavelengths longer than those of visible light onto the temporarily bonding support substrate 10 temporarily bonded to the device substrate 30 from the underlayer 11 side (infrared heating), the heat generable layer 12 is made to generate heat. By this means, the portion 21 of the adhesive 20 adjacent to the interface with the temporarily bonding support substrate 10 can be locally heated so as to cause heat deterioration of the portion 21 of the adhesive 20 with suppressing the influence of heat on the device substrate 30 side.

Yet further, in the first embodiment, in the semiconductor device manufacturing method, the temporarily bonding support substrate 10 can be temporarily bonded to the device substrate 30 via the thermosetting adhesive 20. Then, by making the heat generable layer 12 generate heat to cause heat deterioration of the adhesive 20, cross-linked structures in the portion 21 of the adhesive 20 can be thermally decomposed. By this means, adhesiveness in the portion 21 of the adhesive 20 can be made not to recover even when the temperature drops, and hence the temporarily bonding support substrate 10 can be easily removed from the device substrate 30.

It should be noted that a temporarily bonding support substrate 110 may have a plurality of heat generable layers 121, 122 as shown in FIG. 9. The heat generable layer 122 is placed on the underlayer 11. The heat generable layer 122 covers the principal surface 11a of the underlayer 11. The heat generable layer 121 is placed on the heat generable layer 122. The heat generable layer 121 covers the surface 122a of the heat generable layer 122. The heat generable layer 121 is greater in absorptivity to infrared radiation than the heat generable layer 122. The heat generable layer 122 is greater in absorptivity to infrared radiation than the underlayer 11. The heat generable layer 122 has composition that is intermediate between the composition of the underlayer 11 and the composition of the heat generable layer 121. The temporarily bonding support substrate 110 can be formed such that in terms of the composition ratio of carbon, the heat generable layer 121>the heat generable layer 122>the underlayer 11 as shown in FIG. 9, for example. Thus, when infrared radiation is irradiated toward the heat generable layers 121, 122 from the principal surface 11b side opposite to the principal surface 11a of the underlayer 11, heat generated in the heat generable layers 121, 122 can be collected from the heat generable layer 122 to the heat generable layer 121. As a result, heat necessary to cause heat deterioration of the adhesive 20 (see FIG. 2) covering the surface 121a of the heat generable layer 121 can be efficiently generated at the surface 121a of the heat generable layer 121.

Or a temporarily bonding support substrate 110′ may have a heat generable layer 123 having gradient composition as shown in FIG. 10. The heat generable layer 123 is placed on the underlayer 11. The heat generable layer 123 covers the principal surface 11a of the underlayer 11. The heat generable layer 123 is greater in absorptivity to infrared radiation than the underlayer 11. The heat generable layer 123 is formed such that absorptivity to infrared radiation gradually increases when going from the underlayer 11 side to a surface 123a side. The temporarily bonding support substrate 110′ can be formed such that the composition ratio of carbon of the heat generable layer 123 gradually increases when going from the underlayer 11 side to the surface 123a side as shown in FIG. 10, for example. Thus, when infrared radiation is irradiated toward the heat generable layer 123 from the principal surface 11b side opposite to the principal surface 11a of the underlayer 11, heat generated in the heat generable layer 123 can be moved from the inside of the heat generable layer 123 to the surface 123a. As a result, heat necessary to cause heat deterioration of the adhesive 20 (see FIG. 2) covering the surface 123a of the heat generable layer 123 can be efficiently generated at the surface 123a of the heat generable layer 123.

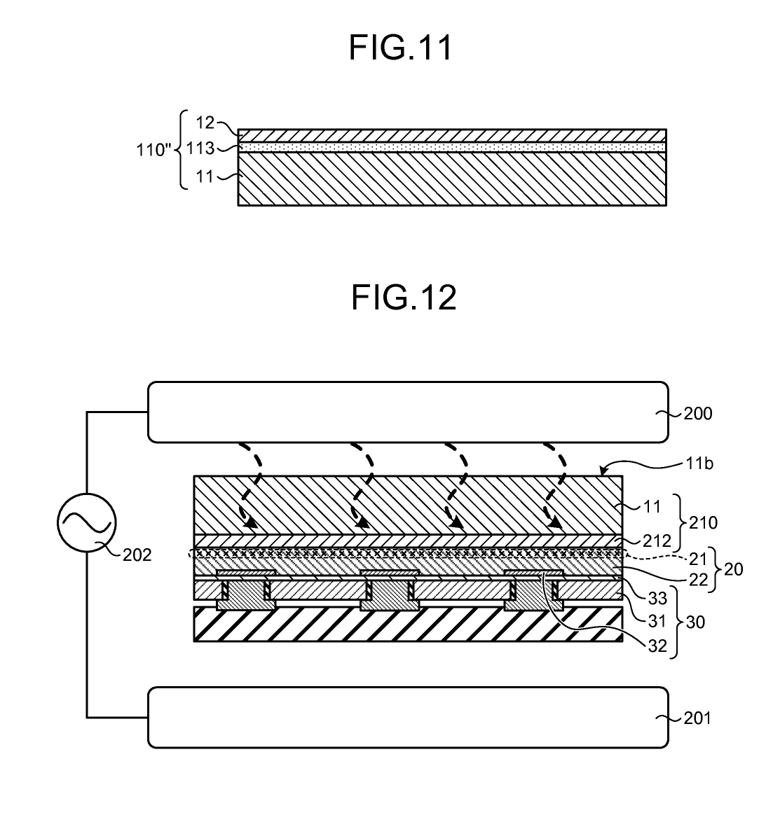

Or a temporarily bonding support substrate 110″ may be formed such that heat generated in the heat generable layer 12 is held in the heat generable layer 12 as shown in FIG. 11. For example, the temporarily bonding support substrate 110″ further has a heat insulating layer 113. The heat insulating layer 113 is placed between the underlayer 11 and the heat generable layer 12. The heat insulating layer 113 is sandwiched between the underlayer 11 and the heat generable layer 12. The heat insulating layer 113 is formed of a material that easily transmits electromagnetic waves of wavelengths longer than those of visible light (e.g., infrared radiation) and easily blocks heat generated in the heat generable layer 12. The heat insulating layer 113 should be resistant to heat. The heat insulating layer 113 is formed of a porous material and may be formed of a material made mainly of, e.g., porous silicon or porous glass. In this case, even if the adhesive 20 is of the hot-melting type or thermoplastic type in the process of FIG. 6, heat generated in the heat generable layer 12 can be held in the heat generable layer 12. Thus, even when some time has elapsed after infrared radiation has been irradiated, the removal can be performed, and thereby an usual room-temperature removal method can be used after the infrared radiation source 100 is evacuated.

### Second Embodiment

Next, a temporarily bonding support substrate 210 according to the second embodiment will be described. Description will be made below focusing on the differences from the first embodiment.

Although the first embodiment illustratively describes the case where the temporarily bonding support substrate 10 has a structure suitable for infrared heating, the second embodiment will illustratively describe the case where the temporarily bonding support substrate 210 has a structure suitable for dielectric heating.

Specifically, as shown in FIG. 12, the temporarily bonding support substrate 210 has a heat generable layer 212 instead of the heat generable layer 12 (see FIG. 1). FIG. 12 is a diagram showing the configuration of the temporarily bonding support substrate 210. The heat generable layer 212 is greater in absorptivity to microwaves than the underlayer 11. The heat generable layer 212 is required to have a large loss factor of dielectric loss (=∈×tan δ, where ∈ is a permittivity and tan δ is a dielectric tangent). For example, the heat generable layer 212 includes a high dielectric layer having metal particles diffused therein. The structure where particles are diffused is advantageous in enlarging tan δ, so that a material of that structure has an ∈ large in value.

In the semiconductor device manufacturing method, instead of the process shown in FIG. 6, the process shown in FIG. 12 is executed. FIG. 12 is a cross-sectional view showing a process of the semiconductor device manufacturing method using the temporarily bonding support substrate 210.

In the process shown in FIG. 12, microwaves are irradiated onto the temporarily bonding support substrate 210 temporarily bonded to the device substrate 30 from the underlayer 11 side.

Specifically, an electrode (microwave source) 200 is placed in a position facing the principal surface 11b of the underlayer 11 of the temporarily bonding support substrate 210, and an electrode 201 is placed on the opposite side of the temporarily bonding support substrate 210 and the device substrate 30 from the electrode 200. High-frequency power is supplied across the electrodes 200 and 201 from a high-frequency power supply 202. Thus, microwaves emitted from the electrode 200 are irradiated onto the temporarily bonding support substrate 210 from the underlayer 11 side as indicated by broken-line arrows in FIG. 12.

At this time, of the temporarily bonding support substrate 210, absorptivity to microwaves in the heat generable layer 212 is greater than absorptivity to microwaves in the underlayer 11. Thus, microwaves irradiated onto the temporarily bonding support substrate 210 are efficiently absorbed by the heat generable layer 212 to make the heat generable layer 212 generate heat. The heat generated in the heat generable layer 212 causes heat deterioration of the portion 21 of the adhesive 20 adjacent to the heat generable layer 212.

Note that, because the temporarily bonding support substrate 210 and the device substrate 30 are placed between the electrodes 200 and 201, it may be difficult to perform removal operation while they stay in this position in the process shown in FIG. 7. In a case where the adhesive 20 is of a thermosetting type, heat deterioration when heated is the thermal decomposition of cross-linked structures in the portion 21, and thus the adhesiveness is hardly likely to recover even when the temperature drops. That is, the removal need not be performed while the heat generable layer 212 is heated to cause heat deterioration of it. Because the removal can be performed when the temperature has dropped, an usual room-temperature removal method can be used after the electrodes 200 and 201 are evacuated.

As described above, in the second embodiment, in the temporarily bonding support substrate 210, the heat generable layer 212 is greater in absorptivity to microwaves than the underlayer 11. Thus, when microwaves are irradiated toward the heat generable layer 212 from the principal surface 11b side of the underlayer 11, the heat generable layer 212 can be made to efficiently absorb the irradiated microwaves to make the heat generable layer 212 generate heat.

Further, in the second embodiment, in the temporarily bonding support substrate 210, the underlayer 11 is formed of a material made mainly of silicon or silicon oxide, and the heat generable layer 212 includes a high dielectric layer having metal particles diffused therein. Thus, absorptivity to microwaves in the heat generable layer 212 can be made greater than absorptivity to microwaves in the underlayer 11. Further, if the underlayer 11 is formed of a material made mainly of silicon, the production cost of the temporarily bonding support substrate 210 can be easily reduced.

Further, in the second embodiment, in the semiconductor device manufacturing method, by irradiating microwaves onto the temporarily bonding support substrate 210 temporarily bonded to the device substrate 30 from the underlayer 11 side (dielectric heating), the heat generable layer 212 is made to generate heat. By this means, the portion 21 of the adhesive 20 adjacent to the interface with the temporarily bonding support substrate 210 can be locally heated so as to cause heat deterioration of the portion 21 of the adhesive 20 with suppressing the influence of heat on the device substrate 30 side.

### Third Embodiment

Next, a temporarily bonding support substrate 310 according to the third embodiment will be described. Description will be made below focusing on the differences from the first embodiment.

Although the first embodiment illustratively describes the case where the temporarily bonding support substrate 10 has a structure suitable for infrared heating, the third embodiment will illustratively describe the case where the temporarily bonding support substrate 310 has a structure suitable for induction heating.

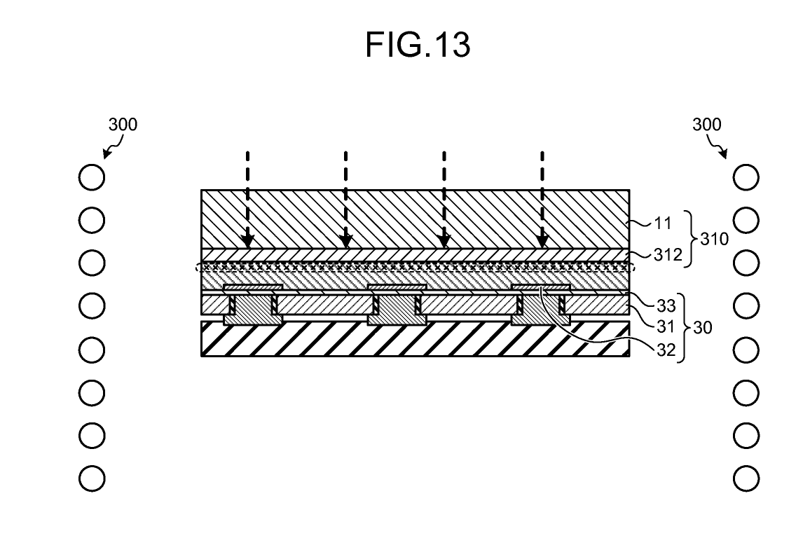

Specifically, as shown in FIG. 13, the temporarily bonding support substrate 310 has a heat generable layer 312 instead of the heat generable layer 12 (see FIG. 1). FIG. 13 is a diagram showing the configuration of the temporarily bonding support substrate 310. The heat generable layer 312 is greater in absorptivity to high frequency waves than the underlayer 11. The heat generable layer 312 is required to be made of a material in which eddy current is likely to occur according to magnetic flux that it receives, and it is effective for the material to have large loss power due to magnetic hysteresis. For example, the heat generable layer 312 may be formed of a material made mainly of metal, especially a material made mainly of a substance large in permeability such as iron, cobalt, or nickel. In the material made mainly of metal, eddy current is likely to occur according to magnetic flux that it receives. The material large in permeability is large in loss power due to magnetic hysteresis.

Further, in the semiconductor device manufacturing method, instead of the process shown in FIG. 6, the process shown in FIG. 13 is executed. FIG. 13 is a cross-sectional view showing a process of the semiconductor device manufacturing method using the temporarily bonding support substrate 310.

In the process shown in FIG. 13, high frequency waves are irradiated onto the temporarily bonding support substrate 310 temporarily bonded to the device substrate 30 from the underlayer 11 side.

Specifically, a coil (high frequency source) 300 is placed to accommodate the temporarily bonding support substrate 310 and the device substrate 30 inside it. Then high-frequency power is supplied to the coil 300 from a high-frequency power supply (not shown). Thus, high frequency waves emitted from the coil 300 are irradiated onto the temporarily bonding support substrate 310 from the underlayer 11 side as indicated by broken-line arrows in FIG. 13.

At this time, of the temporarily bonding support substrate 310, absorptivity to high frequency waves in the heat generable layer 312 is greater than absorptivity to high frequency waves in the underlayer 11. Thus, high frequency waves irradiated onto the temporarily bonding support substrate 310 are efficiently absorbed by the heat generable layer 312 to make the heat generable layer 312 generate heat. The heat generated in the heat generable layer 312 causes heat deterioration of the portion 21 of the adhesive 20 adjacent to the heat generable layer 312.

Note that, because the temporarily bonding support substrate 310 and the device substrate 30 are placed inside the coil 300, it may be difficult to perform removal operation while they stay in this position in the process shown in FIG. 7. Where the adhesive 20 is of a thermosetting type, heat deterioration when heated is the thermal decomposition of cross-linked structures in the portion 21, and thus the adhesiveness is hardly likely to recover even when the temperature drops. That is, the removal need not be performed while the heat generable layer 312 is heated to cause heat deterioration of it. Because the removal can be performed when the temperature has dropped, a usual room-temperature removal method can be used after the coil 300 is evacuated.

As described above, in the third embodiment, in the temporarily bonding support substrate 310, the heat generable layer 312 is greater in absorptivity to high frequency waves than the underlayer 11. Thus, when high frequency waves are irradiated toward the heat generable layer 312 from the principal surface 11b side of the underlayer 11, the heat generable layer 312 can be made to efficiently absorb the irradiated high frequency waves to make the heat generable layer 312 generate heat.

Further, in the third embodiment, in the temporarily bonding support substrate 310, the underlayer 11 is formed of a material made mainly of silicon or silicon oxide, and the heat generable layer 312 is formed of a material made mainly of metal. Thus, absorptivity to high frequency waves in the heat generable layer 312 can be made greater than absorptivity to high frequency waves in the underlayer 11. Further, if the underlayer 11 is formed of a material made mainly of silicon, the production cost of the temporarily bonding support substrate 310 can be easily reduced.

Further, in the third embodiment, in the semiconductor device manufacturing method, by irradiating high frequency waves onto the temporarily bonding support substrate 310 temporarily bonded to the device substrate 30 from the underlayer 11 side (induction heating), the heat generable layer 312 is made to generate heat. By this means, the portion 21 of the adhesive 20 adjacent to the interface with the temporarily bonding support substrate 310 can be locally heated so as to cause heat deterioration of the portion 21 of the adhesive 20 with suppressing the influence of heat on the device substrate 30 side.

### Fourth Embodiment

Next, a temporarily bonding support substrate 410 according to the fourth embodiment will be described. Description will be made below focusing on the differences from the first embodiment.

Although the first embodiment illustratively describes the case where the temporarily bonding support substrate 10 has a structure suitable for infrared heating, the fourth embodiment will illustratively describe the case where the temporarily bonding support substrate 410 has a structure suitable for resistance heating.

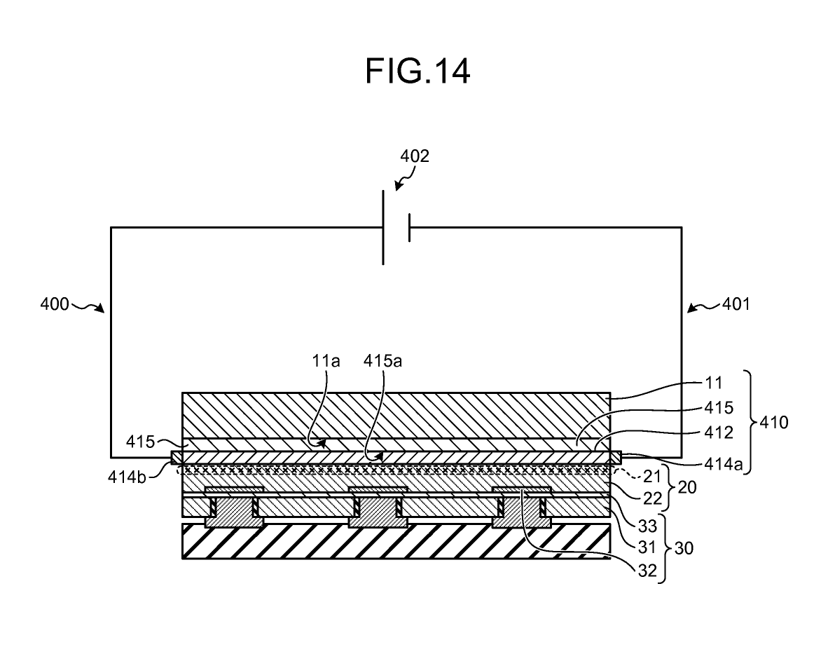

Specifically, as shown in FIG. 14, the temporarily bonding support substrate 410 has a heat generable layer 412 instead of the heat generable layer 12 (see FIG. 1) and further has electrodes 414a, 414b and an insulating layer 415. FIG. 14 is a diagram showing the configuration of the temporarily bonding support substrate 410. The electrodes 414a, 414b are electrically connected to opposite ends of the heat generable layer 412. The electrodes 414a, 414b can be formed, for example, by coating silver paste on opposite ends of the heat generable layer 412. The insulating layer 415 electrically insulates the heat generable layer 412 from the underlayer 11. The insulating layer 415 can be formed by depositing an insulator (e.g., silicon oxide) on the principal surface 11a of the underlayer 11 by a CVD method or the like. Note that, if the underlayer 11 is formed of an insulator such as silicon oxide (glass), the insulating layer 415 may be omitted.

The heat generable layer 412 is greater in the ability to resistance-heat (easiness to enlarge current×(resistance)²) than the underlayer 11. For example, the heat generable layer 412 may be formed of a material made mainly of nickel-chromium alloy or a material made mainly of SiC ceramic. The heat generable layer 412 may be formed by depositing a material made mainly of nickel-chromium alloy on the surface 415a of the insulating layer 415 by a CVD method or the like or by depositing a material made mainly of SiC ceramic on the surface 415a of the insulating layer 415 by chemical vapor deposition or the like. In a case where the heat generable layer 412 is formed of a material made mainly of SiC ceramic, the resistance value decreases with an increase in the temperature at close to use temperatures, so that the thermal runaway of the heat generable layer 412 can be easily suppressed.

In the semiconductor device manufacturing method, instead of the process shown in FIG. 6, the process shown in FIG. 14 is executed. FIG. 14 is a cross-sectional view showing a process of the semiconductor device manufacturing method using the temporarily bonding support substrate 410.

In the process shown in FIG. 14, the temporarily bonding support substrate 410 temporarily bonded to the device substrate 30 is resistance-heated.

Specifically, a direct-current power supply 402 is connected to the electrodes 414a, 414b of the temporarily bonding support substrate 410 via lines 401, 400. Thus, direct-current power is supplied from the direct-current power supply 402 to the heat generable layer 412.

At this time, in the temporarily bonding support substrate 410, the ability to resistance-heat of the heat generable layer 412 is greater than the ability to resistance-heat of the underlayer 11. Thus, direct-current power supplied to the temporarily bonding support substrate 410 is efficiently supplied to the heat generable layer 412 to make the heat generable layer 412 generate heat. The heat generated in the heat generable layer 412 causes heat deterioration of the portion 21 of the adhesive 20 adjacent to the heat generable layer 412.

As described above, in the fourth embodiment, of the temporarily bonding support substrate 410, the heat generable layer 412 is greater in the ability to resistance-heat than the underlayer 11. Thus, when direct-current power is supplied to the temporarily bonding support substrate 410, the direct-current power can be efficiently supplied to the heat generable layer 412 to make the heat generable layer 412 generate heat.

Further, in the fourth embodiment, in the temporarily bonding support substrate 410, the underlayer 11 is formed of a material made mainly of silicon or silicon oxide, and the heat generable layer 412 is formed of a material made mainly of nickel-chromium alloy or SiC ceramic. Thus, the ability to resistance-heat of the heat generable layer 412 can be made greater than the ability to resistance-heat of the underlayer 11. Further, where the heat generable layer 412 is formed of a material made mainly of SiC ceramic, the resistance value decreases with an increase in the temperature at close to use temperatures, so that the thermal runaway of the heat generable layer 412 can be easily suppressed.

Further, in the fourth embodiment, in the semiconductor device manufacturing method, by supplying direct-current power to the temporarily bonding support substrate 410 temporarily bonded to the device substrate 30 via the electrodes 414a, 414b on opposite ends of the heat generable layer 412 (resistance heating), the heat generable layer 412 is made to generate heat. By this means, the portion 21 of the adhesive 20 adjacent to the interface with the temporarily bonding support substrate 410 can be locally heated so as to cause heat deterioration of the portion 21 of the adhesive 20 with suppressing the influence of heat on the device substrate 30 side.

It should be noted that, although the first to fourth embodiments exemplify the heat generable layer that is greater in absorptivity to electromagnetic waves of wavelengths longer than those of visible light than the underlayer 11, the heat generable layer may be greater in absorptivity to electromagnetic waves of wavelengths of visible light than the underlayer 11. If the underlayer 11 is formed of material whose transparency to visible light is high such as glass, it is possible for visible light to be irradiated toward the heat generable layer to generate heat necessary to cause heat deterioration of the adhesive 20 covering the surface of the heat generable layer.

Alternatively, the heat generable layer may be greater in absorptivity to electromagnetic waves of wavelengths shorter than those of visible light than the underlayer 11. If the underlayer 11 is formed of material whose transparency to electromagnetic waves of wavelengths shorter than those of visible light is high such as glass, it is possible for visible light to be irradiated toward the heat generable layer to generate heat necessary to cause heat deterioration of the adhesive 20 covering the surface of the heat generable layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A temporarily bonding support substrate comprising:
an underlayer; and
a heat generable layer provided on the underlayer, a device substrate being to be temporarily bonded to the heat generable layer on an opposite side of the underlayer.

2. The temporarily bonding support substrate according to claim 1, wherein
the heat generable layer has greater absorptivity to electromagnetic waves than the underlayer.

3. The temporarily bonding support substrate according to claim 2, wherein
the heat generable layer has greater absorptivity to infrared radiation than the underlayer.

4. The temporarily bonding support substrate according to claim 3, wherein
the underlayer is formed of a material made mainly of silicon or silicon oxide, and
the heat generable layer is formed of a material made mainly of carbon or tungsten.

5. The temporarily bonding support substrate according to claim 2, wherein
the heat generable layer has greater absorptivity to microwaves than the underlayer.

6. The temporarily bonding support substrate according to claim 5, wherein
the underlayer is formed of a material made mainly of silicon oxide or silicon, and
the heat generable layer includes a high dielectric layer having metal particles diffused therein.

7. The temporarily bonding support substrate according to claim 2, wherein
the heat generable layer has greater absorptivity to high frequency waves than the underlayer.

8. The temporarily bonding support substrate according to claim 7, wherein
the underlayer is formed of a material made mainly of silicon oxide or silicon, and
the heat generable layer is formed of a material made mainly of metal.

9. The temporarily bonding support substrate according to claim 1, wherein
the heat generable layer has greater ability to resistance-heat than the underlayer.

10. The temporarily bonding support substrate according to claim 1, wherein
the underlayer is formed of a material made mainly of silicon oxide or silicon, and
the heat generable layer is formed of a material made mainly of nickel-chromium alloy or SiC ceramic.

11. The temporarily bonding support substrate according to claim 1, further comprising a second heat generable layer placed between the underlayer and the heat generable layer and, has greater absorptivity to electromagnetic waves than the underlayer and smaller absorptivity to electromagnetic waves than the heat generable layer.

12. The temporarily bonding support substrate according to claim 11, wherein
the second heat generable layer has composition that is intermediate between composition of the underlayer and composition of the heat generable layer.

13. The temporarily bonding support substrate according to claim 1, further comprising a heat insulating layer which is placed between the underlayer and the heat generable layer and which transmits electromagnetic waves.

14. The temporarily bonding support substrate according to claim 13, wherein
the heat insulating layer is formed of a material made mainly of porous silicon or porous glass.

15. A semiconductor device manufacturing method comprising:
temporarily bonding a temporarily bonding support substrate having a heat generable layer at a surface of the heat generable layer to a device substrate via adhesive;
making the heat generable layer generate heat; and
removing the temporarily bonding support substrate from the device substrate.

16. The semiconductor device manufacturing method according to claim 15, wherein
the making the heat generable layer generate heat includes causing heat deterioration of the adhesive.

17. The semiconductor device manufacturing method according to claim 15, wherein
the temporarily bonding support substrate further has an underlayer, and
the making the heat generable layer generate heat includes irradiating electromagnetic waves onto the temporarily bonding support substrate temporarily bonded to the device substrate from the underlayer side so as to make the heat generable layer generate heat.

18. The semiconductor device manufacturing method according to claim 17, wherein
the making the heat generable layer generate heat includes irradiating infrared radiation onto the temporarily bonding support substrate temporarily bonded to the device substrate from the underlayer side so as to make the heat generable layer generate heat.

19. The semiconductor device manufacturing method according to claim 17, wherein
the making the heat generable layer generate heat includes irradiating microwaves onto the temporarily bonding support substrate temporarily bonded to the device substrate from the underlayer side so as to make the heat generable layer generate heat.

20. The semiconductor device manufacturing method according to claim 17, wherein
the making the heat generable layer generate heat includes irradiating high frequency waves onto the temporarily bonding support substrate temporarily bonded to the device substrate from the underlayer side so as to make the heat generable layer generate heat.
